(19) United States
(12) Patent Application Publication
(10) Pub. No.: US 2008/0138717 A1
(43) Pub. Date: Jun. 12, 2008

(54) COLOR HOLOGRAPHIC OPTICAL ELEMENT

(76) Inventors: Hans BJELKHAGEN, Leicester (GB); Jim FISCHBACH, Birmingham, MI (US)

Correspondence Address: McDERMOTT WILL & EMERY LLP;34th Floor, 2049 Century Park East, Los Angeles, CA, 90067, US

(21) Appl. No.: 11/775,102

(22) Filed: Jul. 9, 2007

Related U.S. Application Data
(63) Continuation of application No. 11/016,367, filed on Dec. 17, 2004, now abandoned.
(60) Provisional application No. 60/530,588, filed on Dec. 18, 2003.

(51) Int. Cl. G03F 7/00; G02B 5/32

(52) U.S. Cl. 430/2; 359/15

(57) ABSTRACT

A process for producing a color holographic optical element in a real-time interactive multi-channel auto-stereoscopic color image display system, including producing light comprising at least three different monochromatic parts of the optical spectrum from one or more lasers and illuminating a holographic plate with the light from different directions and recorded on a panchromatic light sensitive recording material coated on a suitable substrate.

### CROSS REFERENCE TO RELATED APPLICATION

The present application is a continuation of co-pending U.S. patent application Ser. No. 11/016,367, filed Dec. 17, 2004, which claims the benefit of the filing date of U.S. provisional application Ser. No. 60/530,588, filed on Dec. 18, 2003, entitled “Color Holographic Optical Element,” the content of which is incorporated herein by reference.

### BACKGROUND

1. Field

The present disclosure relates to the field of diffractive optical elements. More particularly, the present disclosure concerns color images produced from diffractive optical elements, where the colors are consistent with true colors of an object. Even more particularly, the present disclosure concerns optical projection systems, primarily intended for 3-D visualization of computer-generated colorized data and images incorporating diffractive optical elements.

2. Background

There are many prior art disclosures relating to diffractive optical elements. However, as is known, the main problem with diffractive optics is the color dispersion that occurs when used in white light, contrary to the use of coherent monochromatic light generated from a laser.

For many applications utilizing a holographic optical element (HOE) as a projection screen for autostereoscopic display systems, color may be important. To make 3-D display systems commercially attractive it should be possible to project high-resolution color images onto the holographic projection screen. The HOE technique described throughout this disclosure will allow for the projection of large-format high-quality color 3-D autostereoscopic images.

### BRIEF DESCRIPTION OF DRAWINGS

Aspects of the present invention are illustrated by way of example, and not by way of limitation, in the accompanying drawings, wherein:

FIG. 1 is a schematic diagram of a typical setup used to record the holographic plate in the process of making a color HOE to be used in a color 3-D display system.

FIG. 2 is a schematic diagram of a side view of a color 3-D autostereoscopic system using an HOE recorded according to the setup presented in FIG. 1.

FIG. 3 is a schematic diagram of a top view of a color 3-D autostereoscopic system using an HOE recorded according to the setup presented in FIG. 1.

### DETAILED DESCRIPTION

The detailed description set forth below in connection with the appended drawings is intended as a description of various embodiments of the present invention and is not intended to represent the only embodiments in which the present invention may be practiced. Each embodiment described in this disclosure is provided merely as an example or illustration of the present invention, and should not necessarily be construed as preferred or advantageous over other embodiments. The detailed description includes specific details for the purpose of providing a thorough understanding of the present invention. However, it will be apparent to those skilled in the art that the present invention may be practiced without these specific details. In some instances, well-known structures and devices are shown in block diagram form in order to avoid obscuring the concepts of the present invention. Acronyms and other descriptive terminology may be used merely for convenience and clarity and are not intended to limit the scope of the invention.

Various systems and techniques will be disclosed for providing real-time interactive multi-channel autostereoscopic color image display system based on a color holographic optical element (HOE) or a holographic beam combiner. The display system or projection screen may be particularly useful in a 3-D display system, such as the one disclosed in U.S. Pat. No. 4,799,739, entitled “Real Time Autostereoscopic Displays Using Holographic Diffusers,” by Newswanger, issued Jan. 24, 1989, (“the Newswanger patent”), the disclosure of which is hereby incorporated by reference.

The color HOE hereof may be produced using at least three different monochromatic parts of the optical spectrum generated from one or more lasers (or other suitable device), emitting at least three different wavelengths in the blue, green, and red parts of the electromagnetic spectrum, illuminating (simultaneously or sequentially) a holographic plate from different directions and recorded on a panchromatic light sensitive ultra-high resolution recording material coated on a suitable substrate (e.g. a glass plate or plastic film). A suitable material for the recording of such large-format color HOEs is a ultra-high resolution silver-halide photographic emulsion that, upon exposure, can be processed in such a way as to generate a high-efficiency, highly color selective optical element of the diffraction type. However, other recording materials, such as photopolymer materials can be used, in particular, for mass production by contact copying color HOEs recorded on silver-halide materials.

A reflective color HOE may be used to avoid cross-talk between the primary colors used for the recording of such an element. In addition, it allows for a 3-D display system using a flat, e.g., wall-mounted projection screen where both the projector and the observer are on the same side in relation to the projection screen. This enables a rather compact display system.

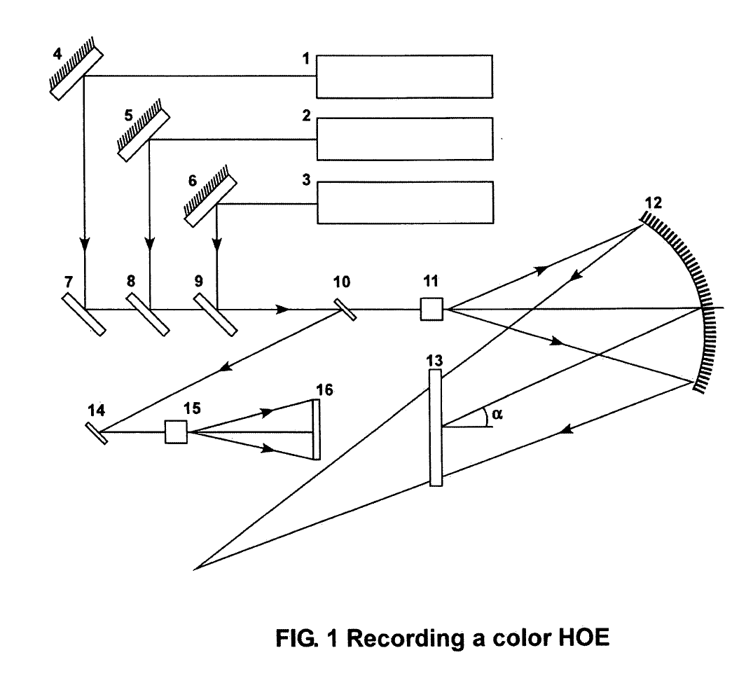

Referring to FIG. 1, there is shown schematically an example of an apparatus for recording a color HOE. The color HOE may be produced by exposing it to coherent light of at least three different wavelengths in the blue, green, and red parts of the visible electromagnetic spectrum emitted from one or more lasers (or other suitable device). Three different lasers may be used, each of which represent a different wavelength where laser 1 emits a red light, laser 2 emits a green light, and laser 3 emits a blue recording light for the recording. The apparatus further may include mirrors 4, 5, and 6, each one associated with an associated laser. The mirrors direct the associated laser beams to associated beam combiners 7, 8, and 9, respectively. These mirrors may be dielectric mirrors with a reflective coating optimized for the laser wavelength to be reflected. Other wavelengths can pass through the beam combiner with very little attenuation. Using the beam combiners it is possible to co-axially combine the three laser beams into one beam containing the three wavelengths, all propagating in the same direction as described below. Instead of the beam combiners, sliding mirrors can be used. In addition, one laser emitting all three wavelengths in one beam of polychrome laser light can also be used here.

The apparatus may also includes a beam splitter 20. After the three laser beams have been combined and are traveling along the same beam path they may be divided into two beams by the beam splitter 10, after which the two beams are propagating in two different directions. One beam from the beam splitter 10 may be directed toward a beam expander and spatial filter 11. The beam expander generates a divergent beam of light to illuminate a concave mirror 12, such as off axis parabolic mirror. The light from the concave minor 12 provides a converging beam of laser light. This converging light or reference beam passes through a holographic plate 13 at a certain angle a. The plate 13 contains a light-sensitive emulsion or material. The other beam from the beam splitter 10 may be directed to a mirror 14 which reflects the beam towards another beam expander and spatial filter 15. The beam expander generates a divergent beam of light to illuminate a diffuser screen 16. The diffuser screen 16 emits light directed toward the holographic plate 13 from the opposite side of the reference beam. The reference beam and the light scattered from the diffusing screen 16 are coherent with each other and both act on the holographic plate 13 during a certain amount of time, i.e. the exposure time.

In making the color HOE, blue light may be exposed first, followed by the green and then the red, by sequentially emitting the light from the three lasers 1, 2, and, 3. Instead of controlling the emission of the laser light by opening and closing the laser beams, such as by using a shutter, the three individual wavelengths can be exposing the holographic plate 13 by sequentially removing the respective mirrors or beam combiners 7 and 8 only. A third possibility is to simultaneously expose the holographic plate by adjusting the output power of each individual wavelength from each laser to match the color sensitivity of the recording material in such a way that the same exposure time can be used for the blue, green, and red wavelengths.

For the recording of a color HOE, the laser wavelengths used can be in the visible range of the electromagnetic spectrum. The blue light can be obtained from an etalon-equipped gas laser (argon-ion laser), the green light from a diode-pumped frequency-doubled Nd:YAG laser and the red light from a helium-neon laser. However, other wavelengths and other lasers can be used with similar results.

The emulsion or the light sensitive material coated on the holographic plate 13 should be sensitive to the three laser wavelengths used for the recording of the color HOE. This emulsion can be an ultra-high-resolution silver-halide emulsion sensitized to the three wavelengths used for the recording. A silver halide emulsion has high sensitivity compared to other possible recording materials, which means that large-format color HOEs can be easily made. These emulsions are well known and commercially available. However, other panchromatic ultra-high-resolution materials such as photopolymer materials can also be considered as described below.

### The Light Sensitive Material.

The ultimate promise of holography is to record and reproduce precisely the desired frequencies, amplitudes, and phases of the wavefronts emanating from an object illuminated with coherent radiation or synthesized from computer graphics. However dramatic the results have been to date, the degree of precision achieved is still far from the theoretical limits.

The principle problems in reaching higher limits involve two critical areas, the recording medium and the recording scheme for generating HOEs. The most popular optical recording medium to date, particularly in the areas of photography and medical X-ray, has been the silver halide emulsions. It has the broad spectral sensitivity and sufficient resolution to meet the existing needs.

However, new technologies are demanding an ever increasing range of spectral sensitivity, higher resolution, greater archival storage permanency, lower noise, higher storage capacity, and greater simplicity. Lacking a generic solution, a unique medium is developed for each application. These materials include dichromated gelatin (DCG), photorefractive crystals, photoresist, photopolymers, and others.

All of these materials have two major deficiencies; namely, low sensitivity and narrow spectral response. In addition, DCG is not commercially available; crystals are expensive and suitable only for highly specialized applications; and photoresist is strictly a two-dimensional recording medium.

Silver halide, on the other hand, incorporates the greatest number of advantages with the minimum of sacrifice. For example, it can: (I) attain high sensitivity over a broad spectral range; (II) be tailored for specialized applications; (III) be coated in a wide range of thicknesses as a 2 D or 3-D media; (IV) be coated on rigid or flexible substrates; (V) be economically produced in any quantity using existing coating technology; and (VI) have excellent storage characteristics before and after use.

In the meanwhile, the field of holography and HOEs is gaining prominence due to its ever broadening applications. The fields of diffractive optics and optical computing are increasingly dependent on its continued development.

Existing media for HOE volume recording include silver halide, DCG, photo-polymers, and other possible materials, such as porous glass. A silver-halide recording photographic material is based on one type, or a combination of silver-halide crystals embedded in a gelatin layer, commonly known as the photographic emulsion. The emulsion may be coated on a flexible substrate, for example, a film, or a stable substrate material, such as glass or the like. There are three types of useful silver halides, silver chloride (AgCl), silver bromide (AgBr), and silver iodide (AgI) commercially used today. Their grain sizes vary from about 10 nanometers for ultra-fine-grained emulsions to a few micrometers for high-sensitive photographic emulsions.

The silver compounds are sensitive to light at various degrees. Silver chloride is only sensitive to violet and UV light. Silver bromide absorbs light up to about 490 nm and if silver iodide is added to silver bromide, the sensitivity extends up to about 520 nm. Special sensitizers (dyes) must be added to the emulsion to make it sensitive to other parts of the spectrum including also sensitivity to infrared light (IR).

### Silver Halide Materials Used for Hoes and Holography

Silver halide recording materials for HOEs are interesting for many reasons. They have high sensitivity in comparison with many other alternative materials. Furthermore, it can be coated on both film and glass; they can cover very large formats; they can record both amplitude and phase holograms, they have high resolving power, and are readily available. Thus, commercial silver halide emulsions for holography are satisfactory for some applications. Nevertheless, they do have some drawbacks, they are absorptive; they have inherent noise and a limited linear response. Also, they are irreversible, need wet processing, and create printout problems in phase holograms, etc.

However, the resolving power is not high enough for many important applications, e.g., color HOEs or color holography.

The manufacturing of photographic emulsions is well known. The preparation of silver halide emulsions is a tedious, complicated process; currently it is difficult to manufacture the ultra fine-grained emulsions needed in many scientific applications. Emulsions exhibiting characteristics different from those typical of the usual commercial products with regard to grain structure, thickness, or spectral sensitivity are generally custom made in the laboratory. There are several scientific applications in which very special emulsions are needed, but are not normally produced by commercial manufacturers of photographic film.

The technique of making silver-halide photographic emulsions has been well-known for over a hundred years. Holographic silver-halide emulsions are, without exception, emulsions of the fine-grained type, often referred to as Lippmann emulsions. For color holography and color HOEs an ultra-high-resolution (silver-halide grain size in the order of 10 nm) emulsion is needed. For producing diffractive color optical elements, the grain size may be of primary importance. To obtain emulsions with ultra-fine grains it can be done by instantaneous emulsification at a low temperature. Rapid melting of the coagulated emulsion in a steam bath make reproducible results. To slow down grain growth during emulsification it is possible to increase the number of growth centers and introduce special growth inhibitors. Grain growth in emulsions may be hampered by the fact that in the emulsification process, a highly diluted solution can be used and then the emulsion concentration is increased by applying a method of gradual freezing and thawing. This type of emulsion manufacturing process can produce emulsions with a grain size of down to about 10 nm. Such high quality and high-resolution emulsions, panchromatically sensitized, are suitable for the manufacturing of color HOEs described herein.

Cross-talk between individual images projected on top of each other on the projection HOE screen may be mainly eliminated by the low-scattering ultra-high-resolution emulsion used for recording the color HOE. However, in order to further eliminate some remaining cross-talk a special processing technique known as SHSG processing, i.e. the generating of Silver-Halide Sensitized Gelatin HOEs, may be used Such HOEs are similar to HOEs recorded on DCG materials. SHSG processing offers high diffraction efficiency which may be important for projecting bright color images using the color HOE described herein. In addition it may reduce or eliminate any scattering noise from the emulsion of the color HOE and may obviate the drawbacks of using DCG as a recording material for producing color HOEs, which have low light sensitivity and limited spectral response (mainly only blue sensitive). Therefore, a lot of interest has been directed at using silver-halide materials processed in such a way that the final hologram will have properties like a DCG hologram. This results in holograms of high efficiency and low scattering. In addition, the SHSG hologram is free from the printout. However, only ultra-fine-grained silver halide emulsions should be considered for SHSG processing.

The chemical processing of the holographic plate 13, upon exposure which comprises developing and bleaching, is done to obtain a high-quality color HOE. Since the silver halide emulsion is rather soft, it should be hardened before the development and bleaching takes place. Emulsion shrinkage and other emulsion distortions caused by the active solutions used for the processing should be avoided. This is in general true for the production of monochrome HOEs as well. In addition, washing and drying of the holographic plate 13 should be done so that no shrinkage occurs. The processing baths and the color processing procedure are dependent on the recording material used. Generally, hardening is accomplished by similarly washing and drying.

Since the color HOE described above is a reflection type of diffractive optical element, the back of the color HOE can be protected by covering it with a light-absorbing black coating, such as black paint, black laminate, or any other absorptive layer index-matched to the emulsion.

After the holographic plate 13 is finished it can be used as a color HOE comprising a projection screen in an autostereoscopic 3-D display system.

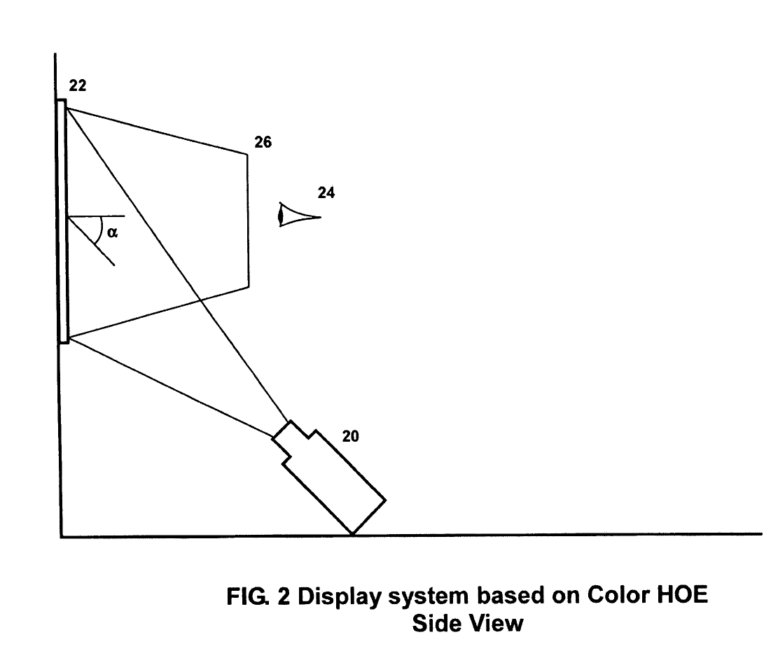

In FIG. 2, there is depicted the application of a color HOE in a 3-D autostereoscopic system. The system is, in principle, similar to the system described in the Newswanger patent referenced above. Here, the color HOE defines the reflection holographic diffuser projection screen.

As shown therein, a single-lens image projector 20 which may be a video, data, movie, or slide projector, projects an image at an angle a (it should be noted that the angle a is equal to the angle used for the recording of the HOE) onto a flat screen 22. Here the screen 22 is wall-mounted.

The color HOE generates a color image which is viewable through an area corresponding to the area of the diffusing screen 16 of FIG. 1 and situated at a certain distance in front of the projection color HOE screen 22. One eye 24 of an observer will receive a color image emitted from the entire area of the projection screen 2. Independent of where the eye is positioned within a viewing area 26, the image color remains constant and accurate over the entire area. Other projectors, located at different positions in regard to projector 20, will generate other color images (e.g., other views of the same object) observable at other locations in space in front of the screen 22. A minimum of two different images are necessary to be projected onto the screen 22 in order to observe an autostereoscopic image.

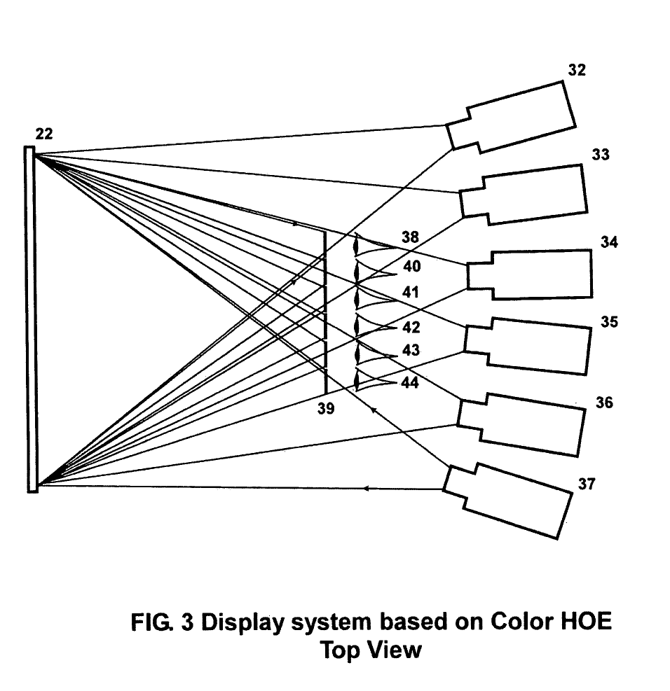

FIG. 3 schematically illustrates a further explanation of how the system operates. Onto the reflection color HOE, different color images are projected from an array of similar single-lens projectors 32, 33, 34, 35, 36 and 37. These projectors are all illuminating the screen from the same vertical angle a. However, each projector is projecting an image at a certain unique angle in the horizontal plane. For example, the projector 22 projects a color image over the entire screen 22 through the viewing zone located along the vertical plane 39. This image is only viewable by an observer's eye located at position 38 in the diagram. At another position 40 in space, in front of the screen, the other eye of the observer will observe a different color image projected from projector 33. Thus, the observer will see a true-color, true 3-D image without using any goggles or other viewing devices. Additional projectors 34, 35, 36 and 37 can provide the observer with different perspectives of the displayed object or computer generated color 3-D images. A minimum of two projectors are needed to generate an autostereoscopic image. Additional projectors can provide different perspectives (e.g., a “look-around”) and more flexibility for the observer to move around in front of the screen. Additional projectors can also make it possible for a second observer to see, simultaneously with the first viewer, the displayed 3-D color image. This may be the same image as the first observer or a completely different 3-D image.

In use the display system may include mirrors in order to fold the beam paths to make a more compact display unit.

The Bragg selectivity of the reflection color HOE eliminates any cross-talk between the three-recorded colors. A completely white viewing zone is generated from the color HOE when pure white light is projected from the projector. This means that there are no color changes when the viewer observes a projected color image and at the same time moves around in the viewing field of the color HOE.

If a transmission color HOE is preferred, it is possible to produce such an optical element provided that the emulsion of the plate is thick enough to suppress any other color than the color used for producing the HOE. The various techniques described throughout this disclosure also enables the production of a transmission color HOE projection screen to be used with projectors located at substantially different positions in space where each set of three projectors project a red, green, and blue image to be combined into a color image on the other side of the projection screen. The reflection color HOE projection screen provides a simpler and more compact and convenient color 3-D display system.

To improve the performance of the described system it is possible to incorporate a head- or eye-tracking system, which means when the viewer moves sideways, the viewing area 26 moves with the viewer to always remain in such a position, so that the eye uninterruptedly can continue to view the image. This process is simultaneously occurring for the viewer's other eye moving the corresponding viewing area for that eye in the same direction. The technique of obtaining this is by using a feedback signal from a commercial head- or eye-tracking system, and to move the projected beams from the projectors by electro-optical, optical or mechanical means, or by combinations thereof. One way to obtain this motion of the viewing area in front of the screen is to rotate a thick flat glass block, through which the projected beam passes, between the projector and the holographic screen. However, it is possible to obtain this effect by other means as well, for example, by mechanically moving the projectors sideways. The eye- or head-tracking system is not limited to these described techniques, but can be obtained in many other ways as well.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A process for producing a color holographic optical element in a real-time interactive multi-channel auto-stereoscopic color image display system, comprising:
producing light comprising at least three different monochromatic parts of the optical spectrum from one or more lasers; and
illuminating a holographic plate with the light from different directions and recorded on a panchromatic light sensitive recording material coated on a suitable substrate.
